(19) United States
(12) Patent Application Publication
(10) Pub. No.: US 2011/0070370 A1
(43) Pub. Date: Mar. 24, 2011

(54) THERMAL GRADIENT ENHANCED CHEMICAL VAPOUR DEPOSITION (TGE-CVD)

(75) Inventors: Kenneth B. K. Teo, Cambridge (GB); Nalin L. Rupesinghe, Cambridge (GB)

(73) Assignee: AIXTRON AG, Herzogenrath (DE)

(21) Appl. No.: 12/954,646

(22) Filed: Nov. 25, 2010

Related U.S. Application Data
(63) Continuation-in-part of application No. PCT/GB2009/001326, filed on May 27, 2009.
(60) Provisional application No. 61/056,619, filed on May 28, 2008.

(51) Int. Cl. C23C 16/46; C23C 16/01

(52) U.S. Cl. 427/255.28; 118/725; 118/723 R

(57) ABSTRACT

A chemical vapor deposition (CVD) apparatus is configured for thermal gradient enhanced CVD operation by the inclusion of multiple heaters, positioned so as to provide a desired thermal gradient profile across a vertical dimension of a substrate or other work piece within the chamber. So configured, the chamber may also be used for controlled growth of thin films via diffusion through intermediate films, either top down or bottom parallel to the direction of the thermal gradient.

### RELATED APPLICATIONS

This is a CONTINUATION-IN-PART of International Application PCT/GB2009/001326, filed 27 May 2009, which claims the priority benefit of U.S. Provisional Patent Application 61/056,619, filed 28 May 2008, each of which is incorporated herein by reference.

### FIELD OF THE INVENTION

The present invention relates to methods and systems for thermal gradient enhanced chemical vapor deposition.

### BACKGROUND

The generally accepted growth mechanism for nanotubes and nanowires is the diffusion of gas through a catalyst. One of the factors controlling the rate of diffusion of the gas is the thermal gradient across the catalyst or substrate (see, e.g., R. T. K. Baker, “Catalytic Growth of Carbon Filaments”, Carbon, v. 27, pp. 315-329 (1989); and R. S. Wagner, in Whisker Technology, A. P. Levitt Ed., p. 47 (Wiley, New York, 1970)). Hence, for the growth of nanotubes and nanowires, especially in a vertical direction above a substrate, it is important to control the thermal gradient vertically.

Referring to FIG. 1, in a hot wall apparatus 10, a heater 12 surrounds a chamber 14 and heats the chamber, and a substrate 16 within the chamber, to a growth temperature. The gases flow horizontally through the chamber and over the substrate 16 to promote growth. The chamber and the substrate are at the same temperature and, hence, it is not possible to form a vertical temperature gradient across the wafer.

Referring to FIG. 2, in a heated substrate apparatus 20, a substrate 22 is placed on a heater 24 in a chamber 26. The substrate is then heated up to the growth temperature. The gases are introduced into the chamber 26 from above (e.g., via gas distributor 28), which cools the top surface of the substrate, and are removed via exhaust 30. This forms a negative temperature gradient because the top side of the wafer is colder than the bottom side of the wafer, which is in contact with the heater. The negative temperature gradient can impede the growth of nanotubes and nanowires. In some cases, a plasma is used to decompose the gases above the substrate, however, the problem of the negative temperature gradient still exists.

Referring to FIG. 3, in hot filament chemical vapour deposition, an apparatus 20′ similar to that used in connection with the heated substrate apparatus 20 is used, except that a thin wire or filament 32 is introduced in chamber 26 between the gas distributor and the substrate 22. The thin wire or filament is used to decompose the gases before they reach the substrate. The thin wire or filament is often operated at temperatures in excess of 1000° C. The wire is often thin and has less than 50% area coverage in order to reduce the heating effects on the substrate. The distance between the wire and the substrate is also fixed.

International application publication WO2008/042691 describes a processing system that includes a substrate holder for supporting and controlling the temperature of a substrate and a hot filament hydrogen radical source for generating hydrogen radicals. The hot filament hydrogen radical source includes a showerhead assembly with a showerhead plate having gas passages facing the substrate for exposing the substrate to the hydrogen radicals, and at least one metal wire filament to thermally dissociate H₂ gas into the hydrogen radicals.

US PGPUB 2002/0132374 describes a deposition process that includes modification of deposition system component parameters (e.g., heating a showerhead or adjusting a distance between a showerhead of the deposition system and a wafer upon which a film is to be deposited), to control the characteristics of a dielectric film.

US PGPUB 2001/0035124 describes a processing apparatus that includes an upper heater and a lower heater formed above and below a heating chamber. A shower plate is located between the upper heater and the lower heater. N₂ gas is introduced in a gas heating space between the upper heater and the shower plate and is then supplied to the substrate in the form of a shower via the shower plate. The substrate is subjected to convection heat transfer from the N₂ gas that undergoes radial heat transfer from the upper heater, as well as from the heated N₂ gas, and is also heated by the lower heater.

US PGPUB 2004/0129224 describes a processing apparatus with a showerhead for introducing a process gas into a processing vessel, and heaters for heating the showerhead at an elevated temperature. A cooling liquid control system controls the flow of a cooling liquid while the showerhead is being heated and cooled.

JP 2008/001923 describes a film deposition apparatus with substrate heating means for heating a substrate placed on a stage, a showerhead facing the stage and having a large number of gas discharge holes, cooling means provided above the showerhead to cool the shower head, and heating means provided above the cooling means to heat the showerhead via the cooling means.

### SUMMARY OF THE INVENTION

In one embodiment, the present invention provides a vapour deposition apparatus that includes a chamber configured for chemical vapour deposition of a film on a substrate and which has included therein a lower heater configured to support said substrate and an upper heater disposed a vertical distance above the lower heater. The upper heater has holes therethrough to allow reaction gases to pass vertically from a gas distributor within the chamber towards the substrate. In some instances, area coverage of the upper heater is greater than 50%. Also, either or both of the upper heater and the lower heater may be configured for vertical motion with respect to one another in order to facilitate adjustment of the vertical distance between the heaters. In some cases, the upper heater is integrated with the gas distributor.

A further embodiment of the invention provides a vapour deposition apparatus that includes a chamber configured for chemical vapour deposition of a film on a substrate and having included therein a lower heater configured to support said substrate and an upper heater disposed a vertical distance above the lower heater, the upper heater being positioned above a gas distributor having holes therethrough to allow reaction gases to pass vertically towards the substrate.

Still another instantiation of the vapour deposition apparatus provides a chamber configured for chemical vapour deposition of a film on a substrate and having included therein a lower heater configured to support said substrate and an upper heater disposed a vertical distance above the lower heater, the upper heater being positioned circumferentially around a gas distributor having holes therethrough to allow reaction gases to pass vertically towards the substrate.

In any or all of the foregoing embodiments, the bottom heater may include a cooling element. Likewise, either or both of the upper and lower heaters may be configured for the application of a voltage to create a plasma.

A method consistent with an embodiment of the invention involves establishing a thermal gradient between an upper heater and a lower heater within a vacuum chamber in which a substrate is positioned in the vicinity of the lower heater, and introducing reaction gasses vertically into the chamber to create depositions on the substrate. The upper heater may be maintained higher or lower in temperature than the lower heater and the reaction gasses may be evacuated from the chamber using a vacuum pump after being made to flow vertically through holes in the upper heater prior to encountering a top surface of the substrate.

Additional embodiments of the invention provide an apparatus having a chamber configured for chemical vapour deposition of a film on a substrate, and including therein a lower heater configured to support the substrate and a gas distributor having an upper heater disposed a vertical distance above the lower heater. The upper heater has a first heating stage with individually heated gas supply lines, and a second heating stage with individually heated gas supply tubes. Multiple ones of the gas supply tubes are supplied by a common one of the gas supply lines. The gas distributor has holes therethrough, each of the holes being aligned with one or more of the individually heated gas supply tubes to allow reaction gases to pass vertically within the chamber from the gas distributor towards the substrate.

Still further embodiments of the invention provide for establishing a thermal gradient by means of a temperature differential between a multi-stage upper heater and a lower heater vertically displaced therefrom within a vacuum chamber in which a substrate is positioned in the vicinity of the lower heater, and introducing reaction gasses vertically into the chamber to create depositions on the substrate.

These and other features and embodiments of the present invention are described further below.

### BRIEF DESCRIPTION OF THE DRAWINGS

The present invention is illustrated by way of example, and not limitation, in the figures of the accompanying drawings, in which:

FIG. 1 illustrates a conventional apparatus in which substrates are heated by way of heating elements surrounding a chamber.

FIG. 2 illustrates a conventional chamber configured with a single substrate heating element.

FIG. 3 illustrates a chamber configured for conventional, hot filament, chemical vapour deposition (CVD) on a substrate.

FIG. 4 illustrates an apparatus configured in accordance with one embodiment of the present invention, employing both top and bottom heating elements in a chamber configured for growing nano-structures on substrates.

FIGS. 5A and 5B illustrate alternative configurations of apparatus configured for thermal gradient enhanced CVD in accordance with embodiments of the present invention.

FIGS. 6A and 6B illustrate first and second heating stages, respectively, of a multi-stage upper heating apparatus configured in accordance with an embodiment of the present invention.

FIGS. 7A and 7B are images taken of sample wafers, showing the growth of nano-structures in apparatus configured in accordance with embodiments of the present invention.

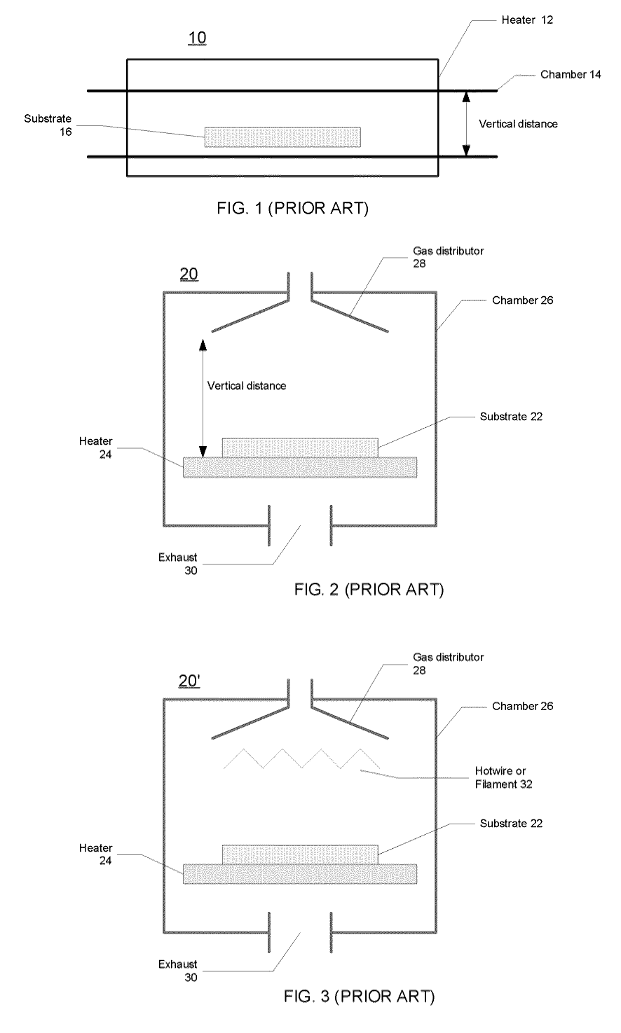

### DETAILED DESCRIPTION

Described herein are methods and systems for thermal gradient enhanced chemical vapor deposition (TGE-CVD). In various instantiations, the present invention provides a CVD (or other form of deposition) chamber which includes both an upper and lower heater or heating element. The lower heater (which, during operation, may be maintained at a temperature of between 20-1000° C.) may be configured to support a substrate or other work piece, and the upper heater (which, during operation, may be maintained at a temperature of between 20-1000° C.) is disposed a certain distance (e.g., 5-75 mm) above the lower heater. In some instances, the upper heater may have holes running therethrough, to allow reaction gases to pass vertically from a gas distributor within the chamber towards the substrate. For example, the upper heater may be integrated with the gas distributor.

Either or both of the upper and/or lower heater(s) may be configured for vertical motion relative to one another. This facilitates adjustment of the vertical distance between the heaters. Further, the area coverage of the upper heater may be greater than 50%.

An alternative instantiation involves a CVD (or other form of deposition) chamber having included therein a lower heater configured to support a substrate and an upper heater disposed a vertical distance above the lower heater, and above a gas distributor. This arrangement allows reaction gases to pass unimpeded in a vertical direction towards the substrate.

Still another instantiation provides an apparatus that includes a CVD chamber. Included in the CVD chamber is a lower heater configured to support a substrate and an upper heater disposed a vertical distance above the lower heater, and being positioned circumferentially around a gas distributor having holes therethrough to allow reaction gases to pass vertically towards the substrate. In some instances, the lower heater may include a cooling element. Further, either or both of the upper and lower heaters may be configured for the application of a voltage to create a plasma.

Regardless of the physical instantiation, systems configured in accordance with the present invention are able to establish a thermal gradient between an upper heater and a lower heater within a vacuum chamber in which a substrate is positioned (usually, though not necessarily in the vicinity of the lower heater). Reaction gasses are introduced vertically into the chamber to create depositions on the substrate and the temperature gradient is preserved by maintaining one of the heaters higher in temperature than the other.

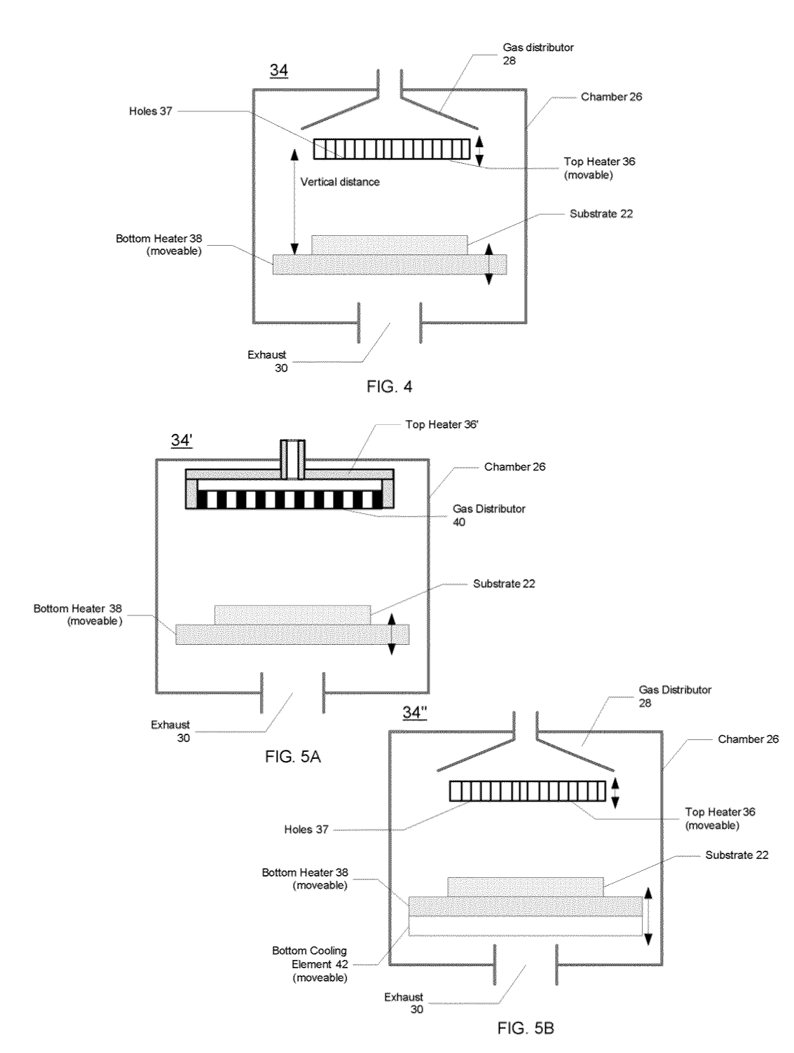

Now referring to FIG. 4, an apparatus 34 configured for thermal gradient enhanced CVD in accordance with an embodiment of the present invention is illustrated. The substrate 22 is placed on a bottom heater 38 within chamber 26. This may be done using a conventional vacuum robotic wafer handler as is known in the art. A top heater 36, with holes 37 therethrough to allow the reaction gases to pass vertically from the gas distributor 28 to the substrate 22, is suspended above the substrate 22. The area coverage of the top heater is preferably greater than 50%, to maximise the efficiency of the top heater in creating a vertical thermal gradient within the chamber. Either or both of the top heater 36 or the bottom heater 38 may be moved vertically in order to facilitate the adjustment of the vertical distance between the heaters.

The difference in temperature between the heaters, as well as the distance between the heaters, can be used to control the thermal gradient across the vertical dimension of substrate 22. For example, if the top heater is higher in temperature than the bottom heater, a positive thermal gradient (from the top of the substrate to the bottom of the substrate) is formed. On the other hand, if the bottom heater is higher in temperature than the top heater, a negative thermal gradient (from the top of the substrate to the bottom of the substrate) is formed.

A variety of different chamber/heater configurations may be employed. For example, FIG. 5A shows a configuration in which the apparatus 34′ includes a top heater 36′ (which may be moveable or fixed) that is integrated with a gas distributor 40. Gas distributor 40 may be configured as a showerhead, with multiple gas exit ports or injectors to provide gasses in the direction of the substrate. In this particular instance, the top heater 36′ is positioned above the showerhead 40, but other embodiments may incorporate these elements in different fashions. For example, the heater element may be positioned circumferentially around the showerhead or centrally therein.

Yet a further embodiment is illustrated in FIG. 5B. In this implementation, the apparatus 34″ includes a bottom heater 38, which itself includes a cooling element 42. Both the bottom heater 38 and the cooling element 42 may be moveable (either collectively or independently of one another) so as to maintain a constant temperature of the substrate 22 if there is excessive radiative heating from the top heater 36 in situations where the top heater is moved into close proximity with the substrate to create a large thermal gradient. Additionally, in any of the above-described configurations, voltages can be applied to the top and/or bottom heaters to create a plasma.

In addition to controlling the temperature gradient across the substrate by means of independently moveable top and/or bottom heaters, as discussed above, it is also important to encourage gas phase reactions. The inventors have determined that good growth conditions for carbon nano-structures correspond to showerhead temperatures on the order of approximately 850° C., at which temperatures new radicals have been observed to form. In order to increase the path and heating efficiency of the gas introduced into the chamber, a two-stage heating process can be employed before the gas comes into contact with the final heated showerhead plate.

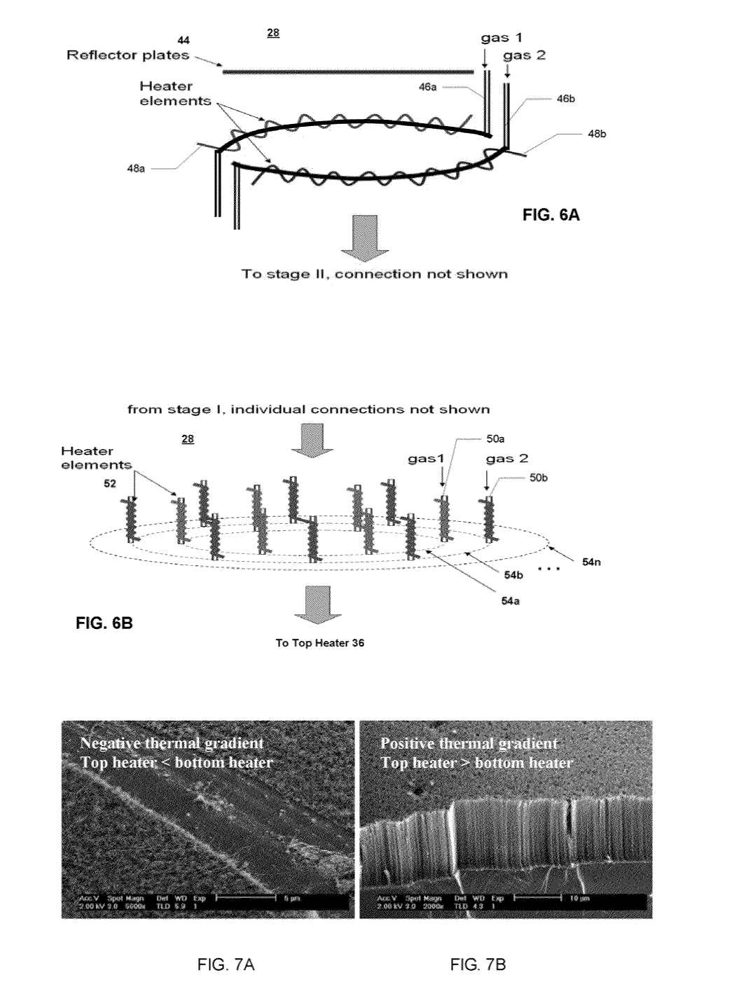

As shown in FIGS. 6A and 6B, the first part of the two stage heating process may be effected by a first stage of a gas distributor 28 in which gas supply lines 46a, 46b are heated via coiled heating elements 48a, 48b. These heating coils may be controlled independently of one another so that each of the supply gasses provided via gas supply lines 46a, 46b are heated to optimal temperatures, or the heating coils may be controlled via a common heating control. One or more reflector plates 44 may be provided for radiant heating. Note that although two gas supply lines are shown in this illustration, other embodiments of the invention may employ more or fewer numbers of gas supply lines, each with their respective heating coil.

The second part of the two stage heating process involves additional individual heating coils. As shown in FIG. 6B, from the first stage the supply gasses are provided via the gas supply lines 46a, 46b to individual gas supply tubes 50a, 50b. Notice that there are a number of gas supply tubes 50a, for gas provided from gas supply line 46a, and a number of gas supply tubes 50b, for gas provided from gas supply line 46b. The number of gas supply tubes 50a may be more than, less than or equal to the number of gas supply tubes 50b. In general, the gas supply tubes may be positioned in a number of concentric rows 50a, 50b, . . . , 50n, about a center (or other point) of the gas distributor 28, and the different rows may have different numbers of the various gas supply tubes 50a, 50b, depending on the type of gas dispersal characteristics desired.

Each of the individual gas supply tubes 50a, 50b are heated via coiled heating elements 52. These heating coils for the different gas supply tubes 50a, 50b may be controlled independently of one another so that each of the supply gasses provided via gas supply tubes 50a, 50b are heated to optimal temperatures, or the heating coils may be controlled via a common heating control. Note that although two groups of gas supply tubes are shown in this illustration, other embodiments of the invention may employ more or fewer groups of gas supply tubes (in general according to the number of gas supply lines from the first heating stage), each with their respective heating coil.

From this second stage of the two stage heating process, the individual gas supply tubes 50a, 50b supply their respective gasses to the top heater 36 illustrated in FIG. 4. The individual gas supply tubes 50a, 50b may align with the holes 37 of the heater, or, in some instances, two or more gas supply tubes may share one hole 37 of the top heater 36. In addition, this top heater 36 may be used as a thermal barrier to prevent sharp thermal gradients for gasses leaving tubes 50a and 50b.

FIGS. 7A and 7B are images taken of sample wafers, each at 650° C., and illustrate the growth of nano-structures in apparatus configured with top and bottom heaters in accordance with embodiments of the present invention. In FIG. 7A, the growth was conducted in a negative thermal gradient environment, in which the top heater had a temperature lower than the bottom heater. In FIG. 7B, the growth was conducted in a positive thermal gradient environment, in which the top heater had a temperature greater than the bottom heater.

It should be appreciated that many details of an apparatus suitable for performing the nano-structure growth operations described herein have not been presented in detail so as not to unnecessarily obscure the features of the present invention. Such details would, of course, be required for an operational system, but are known in the art. For example, U.S. Pat. No. 5,855,675, assigned to the assignee of the present invention and incorporated herein by reference, provides a good discussion of features which may included in an apparatus that also includes dual heaters in accordance with the present invention. In general, such a commercial apparatus may be organized as a cluster-tool-based processing system operating substantially within a vacuum chamber. A wafer transfer apparatus may be positioned to operate from the center of the vacuum chamber and be adapted to place and retrieve, by rotation and extension, substrates, typically semiconductor wafers, from and to processing chambers configured in the manner described above and appended at points around the periphery of substantially circular (or square or other shape) vacuum transfer chamber. Wafers may be moved from an outside environment into the vacuum chamber through a load-lock, then through one or more processing chambers, and finally back to the outside environment through an unload lock. Gases used in processing may be introduced via a gas feed and control unit through conduit(s) and manifolds, such as the showerhead manifold discussed above. Alternatively, other gas distributor manifolds may be used.

The processing chambers are typically maintained at atmospheric pressure or below atmospheric pressure through the use of vacuum pumps fluidly coupled to the chamber exhausts. This avoids contamination by atmospheric gases and other particles. During processing in one of the processing chambers, vacuum pumping may be throttled to control process chamber pressure without using excessive quantities of process gases. Such throttling may be accomplished in a number of ways, including by valves having controllable openings. In a typical process cycle, after processing is complete, gases are valved off and the throttling mechanism is opened to allow maximum pumping speed in the processing chamber. The purpose is to reduce the gas pressure in the processing chamber to a value close to that in the substrate transfer chamber. Then, the processed wafer may be removed from the chamber.

A drive assembly mounted below a processing chamber may be used to raise and lower an internal pedestal on which the substrate support (e.g., the bottom heater) is attached. Alternatively, the bottom heater may be included within such a pedestal. Usually though, the pedestal apparatus will have a heated hearth for supporting and providing heat to a wafer to be processed. When the pedestal is in a lowermost position wafers may be inserted into the chamber and released to lie upon the hearth, and, after the transfer apparatus withdraws, the pedestal may be raised, moving the supported wafer up into a processing position to be processed. The procedure may be reversed when the wafer is to be removed from the processing chamber. Vacuum integrity may be maintained for the overall assembly while allowing vertical freedom of motion for the pedestal by means of a bellows. It will be apparent to those of ordinary skill in the art that there are other mechanisms by which the pedestal assembly may be translated in a vertical fashion, and there are a variety of alterations that might be made without departing from the scope of the invention. There are, for example, a number of different extensible drives that might be used, such as air cylinders, air-oil systems, hydraulic systems, and the like.

Thus, means for thermal gradient enhanced chemical vapor deposition have been described. Although discussed with reference to several illustrated embodiments, the present invention is not intended to be limited by the examples provided in these illustrations. For example, the methods and system of the present invention may also be used for controlled growth of thin films via diffusion through intermediate films, either top down or bottom parallel to the direction of the thermal gradient.

What is claimed is:

1. An apparatus, comprising a chamber configured for chemical vapour deposition of a film on a substrate, said chamber having included therein a lower heater configured to support said substrate and a gas distributor having an upper heater disposed a vertical distance above the lower heater, the upper heater having a first heating stage with individually heated gas supply lines, a second heating stage with individually heated gas supply tubes, multiple ones of the gas supply tubes being supplied by a common one of the gas supply lines, and holes therethrough, each of said holes aligned with one or more of the individually heated gas supply tubes to allow reaction gases to pass vertically within the chamber from the gas distributor towards the substrate.

2. The apparatus of claim 1, wherein area coverage of the upper heater is greater than 50%.

3. The apparatus of claim 1, wherein the upper heater and the lower heater are adjustable with respect to one another in terms of their vertical separation distance from one another.

4. The apparatus of claim 1, wherein the bottom heater includes a cooling element.

5. The apparatus of claim 1, wherein either or both of the upper heater and the lower heater is configured for the application of a voltage to create a plasma.

6. An apparatus, comprising: a chamber configured for chemical vapour deposition of a film on a substrate and having included therein a lower heater configured to support said substrate, a gas distributor configured to allow reaction gases to pass vertically towards the substrate, and a multi-stage upper heating arrangement configured to present a heating plane between the gas distributor and the substrate with an area coverage of more than 50% and being adjustable in vertical displacement from the lower heater.

7. The apparatus of claim 6, wherein the bottom heater includes a cooling element.

8. The apparatus of claim 6, wherein either or both of the upper heating arrangement and the lower heater is configured for the application of a voltage to create a plasma.

9. A method, comprising establishing a thermal gradient by means of a temperature differential between a multi-stage upper heater and a lower heater vertically displaced therefrom within a vacuum chamber in which a substrate is positioned in the vicinity of the lower heater, and introducing reaction gasses vertically into the chamber to create depositions on the substrate.

10. The method of claim 9, wherein the upper heater is maintained higher in temperature than the lower heater, thereby providing a positive thermal gradient.

11. The method of claim 9, wherein the lower heater is maintained higher in temperature than the upper heater, thereby providing a negative thermal gradient.

12. The method of claim 9, further comprising evacuating the reaction gasses from the chamber using a vacuum pump.

13. The method of claim 9, wherein the reaction gasses are made to flow vertically through holes in the upper heater prior to encountering a top surface of the substrate.

14. The method of claim 9, wherein the reaction gasses are made to flow vertically through individually heated gas supply lines in the upper heater prior to encountering a top surface of the substrate.

15. The method of claim 9, wherein the reaction gasses are made to flow vertically through individually heated gas supply lines and individually heated gas supply tubes in the upper heater prior to encountering a top surface of the substrate, wherein multiple ones of the gas supply tubes are supplied by a common one of the gas supply lines.
